(19) United States
(12) Patent Application Publication
(10) Pub. No.: US 2026/0093892 A1
(43) Pub. Date: Apr. 2, 2026

(54) UNIVERSAL ROUTABILITY PREDICTION METHOD BASED ON FEW-SHOT LEARNING

(71) Applicant: FUZHOU UNIVERSITY, Fuzhou (CN)

(72) Inventors: Genggeng LIU, Fuzhou (CN); Zhenkun LIN, Fuzhou (CN); Wenzhong GUO, Fuzhou (CN)

(21) Appl. No.: 19/037,322

(22) Filed: Jan. 27, 2025

(30) Foreign Application Priority Data
Sep. 27, 2024 (CN) 202411360708.8

(51) Int. Cl. G06F 30/398; G06F 30/3947

(52) U.S. Cl. CPC G06F 30/398; G06F 30/3947

(57) ABSTRACT

The present invention relates to a universal routability prediction method based on few-shot learning and belongs to the technical field of computer-aided design of integrated circuits. A universal routability prediction is converted into a meta learning scenario, and a prediction method based on the few-shot learning (FSL) is provided. The method only needs to provide a feature of a query chip and a label pair example set, to flexibly adapt to a new prediction task without additional training. For a data imbalance problem generally existing in the field of electronic design automation, the present invention further introduces a meta learning policy based on importance sampling for optimizing a training process of a model. To train the provided method, an FSL dataset based on CircuitNet and ISPD2015 datasets is constructed.

### TECHNICAL FIELD

The present invention belongs to the technical field of computer-aided design of integrated circuits, and specifically relates to a universal routability prediction method based on few-shot learning.

### BACKGROUND

The continuous reduction of design feature sizes of Very-Large-Scale-Integration (VLSI) circuits and the increasing complexity of on-chip connectivity present challenges to the scalability of electronic design automation (EDA) technology. Routability is one of the most challenging issues in the EDA process, and the core target is to use data from the placement phase to evaluate the routing difficulty of chip design. Typical metrics include routing congestion and the distribution of Design Rule Check (DRC) violations. Routing has been proven to be an NP-hard problem, which leads to a long feedback cycle in the design process. It is particularly critical to quickly and accurately predict routability in an early design phase, which helps improve the efficiency of feedback and accelerate the convergence of the design process. Predicting results in the early design phase through Machine Learning (ML) to promote the optimization of design steps has become a popular method in EDA, providing faster convergence and reducing pessimism.

The key challenges of performing routability prediction through ML include dataset missing, data imbalance, and domain shift problems. This is a major obstacle to using ML for routability prediction. Different application scenarios put forward diverse design targets for chips, which requires customized adjustments to EDA tools and continuous updating of routability prediction tasks. To meet these challenges, chip design engineers need to train models from scratch or fine-tune existing models. However, the training of neural networks not only requires machine learning knowledge, but also depends on computing resources, annotated data, and human labor. This is almost an insurmountable obstacle for engineers who lack these resources, thereby affecting the efficiency of chip design.

FSL aims to quickly learn and adapt to new tasks through a small amount of data annotations, thereby effectively alleviating the problem of data scarcity. In the chip design, the same Register Transfer Level (RTL) design is often reused, and differentiated optimization is performed through the EDA process.

### SUMMARY

A purpose of the present invention is to provide a universal routability prediction method based on few-shot learning, to flexibly process different routability metrics, chip types, design scales, manufacturing technologies, and unknown tasks, thereby implementing a universal routability prediction.

To achieve the above purpose, the technical solutions of the present invention are as follows: a universal routability prediction method based on few-shot learning, where a universal routability prediction is converted into a meta learning scenario, and a prediction method based on the few-shot learning (FSL) is provided, to implement a routability prediction of a query chip.

### In an Embodiment of the Present Invention, the Method Includes:

defining a universal routability prediction task T of a chip layout divided into a W×H grid as T: X→Y∈ [symbol] , where X represents a used chip feature; and the task includes different routability metrics (for example, congestion and DRC violations), technical nodes (for example, 28 nm and 14 nm), chip types (for example, a CPU, a GPU, and an AI chip), and RTL designs (for example, different scales and design targets);
modeling the universal routability prediction task as a meta learning scenario, constructing a universal few-shot learner F, and by using chip data (support set S^{T}) with a same RTL design as an unseen chip design (query X_{q}), adapting to any routability prediction task T, to generate an accurate routability prediction Y_{q}=F(X_{q}, S^{T}), S^{T}={(Xᵢ, Yᵢ)}i≤N; and by using a meta training dataset Dₜᵣₐᵢₙ including a plurality of routability prediction tasks, training a routability prediction model through meta learning, to enable the routability prediction model to acquire general knowledge during a plurality of times of FSL processes;
to fully use spatial correlation information between a chip feature and a label, modeling the universal routability prediction task as a dense prediction problem T: X∈ [symbol] →Y∈ [symbol] , and using four features widely used in the routability prediction task; and
for a routability prediction task t of a chip design, using, by the routability prediction model, a query

$${x}_{q}^{t}$$

and a support set

$${S}^{t} = {\{ ( {x}_{i}^{t} , {y}_{i}^{t} ) \}}_{i < N}$$

that is composed of a chip feature with the same RTL design and a label thereof as inputs; and in the support set, performing cascading by each chip feature and the label thereof in a channel dimension, and promoting information interaction between the support set and the query through a cross block, thereby accurately predicting a routability result

$${\hat{y}}_{q}^{t} = F ( {x}_{q}^{t} , {S}^{t} ) .$$

In an embodiment of the present invention, in the training the routability prediction model through meta learning, to enable the routability prediction model to acquire general knowledge during a plurality of times of FSL processes, an importance sampling technology is introduced for the meta learning, to optimize losses of the model on different tasks, and a target is to enable the model to self-adaptively perform task sampling [symbol] =Eₜ_{_{B}}_{|p}_{^{t}}[L^{t}/p^{t}], where p^{t}μ \sqrt{E[L^{t2}]} and Σp^{t}=1 according to dynamic changes of different task losses Lₜ in a training process; and each task retains 10 recent historical loss values and performs dynamic updating in the training process.

In an embodiment of the present invention, before the training is started, a batch B of tasks t are selected through random sampling, and after 10 samples are collected for each task, a meta learning policy based on importance sampling is initiated; in a task sampling phase, to introduce randomness and prevent the model from forgetting past knowledge, a constant γ=0.01 is added when a probability p^{t} of task sampling is calculated, and a quantity of tasks in the meta training dataset Dₜᵣₐᵢₙ is n; a batch B of tasks t_{B} are sampled based on p^{t}; a query

$${Q}_{b}^{t} ← ( {x}_{b}^{t} , {y}_{b}^{t} )$$

and a support set

$${S}_{b}^{t} ← {\{ ( {x}_{i}^{t} , {y}_{i}^{t} ) \}}_{i \leq N}$$

are sampled from each task t_{b∈B}; to prevent overfitting of the model on a specific task and improve data diversity, data enhancement is performed on the query Q_{b}^{t} and the support set S_{b}^{t} separately; and finally, the training improves accuracy of the routability prediction of the model for a given query under a condition that S^{t} is the support set, to enable the model to acquire general knowledge related to the FSL through the meta learning.

In an embodiment of the present invention, the four features widely used in the routability prediction task are: rectangular uniform wire density (RUDY), RUDY pin, macro region, and unit density.

In an embodiment of the present invention, in a process of accurately predicting the routability result

$${\hat{y}}_{q}^{t} = F ( {x}_{q}^{t} , {S}^{t} )$$

for the routability prediction task t of the chip design, UniverSeg is used as a result backbone, to adapt to different sizes of support sets.

In an embodiment of the present invention, the meta training dataset Dₜᵣₐᵢₙ is constructed based on CircuitNet and ISPD2015 datasets.

In an embodiment of the present invention, a dataset corresponding to each routability prediction task of the chip design constructs three disjoint splits d={dₛ,dᵥ,dₜ}, respectively containing 60%, 20%, and 20% of data; and the model uses a support split dₛ and a test split dₜ in a training set to train the model and uses a verification split dᵥ to perform model selection and hyperparameter tuning.

The present invention further provides a universal routability prediction system based on few-shot learning, including a memory, a processor, and a computer program instruction that is stored on the memory and can be executed by the processor, where when the processor executes the computer program instruction, the method steps described above can be implemented.

The present invention further provides a computer-readable storage medium storing a computer program instruction that can be executed by a processor, where when the processor executes the computer program instruction, the method steps described above can be implemented.

Compared with the prior art, the present invention has the following beneficial effects: According to the method in the present invention, the universal routability prediction is converted into the meta learning scenario, and the prediction method based on the few-shot learning (FSL) is provided. The method only needs to provide a feature of a query chip and a label pair example set, to flexibly adapt to a new prediction task without additional training. For a data imbalance problem generally existing in the field of electronic design automation, the present invention further introduces a meta learning policy based on importance sampling for optimizing a training process of a model. To train the provided method, an FSL dataset based on CircuitNet and ISPD2015 datasets is constructed. According to the method in the present invention, different routability metrics, chip types, design scales, manufacturing technologies, and unknown tasks can be flexibly processed, thereby implementing a universal routability prediction.

### BRIEF DESCRIPTION OF THE DRAWINGS

FIG. 1 is an architecture diagram of a model of a method according to the present invention.

### DETAILED DESCRIPTION OF THE EMBODIMENTS

The technical solution of the present invention is described below in detail with reference to the accompanying drawings.

It should be noted that the following detailed description is exemplary and aims to further describe the present application. Unless otherwise stated, all technical and scientific terms used herein have the same meaning as those commonly understood by those of ordinary skill in the art of the present application.

It should be noted that the terms used herein are only for describing the embodiments rather than for limiting the exemplary embodiments of the present application. As used herein, unless otherwise stated clearly in the context, a singular form is intended to include a plural form thereof. In addition, it should be understood that the terms “comprise” and/or “include” as used herein indicate the presence of features, steps, operations, components, assemblies, and/or combinations thereof.

The present invention provides a universal routability prediction method based on few-shot learning. A universal routability prediction is converted into a meta learning scenario, and a prediction method based on the few-shot learning (FSL) is provided, to implement a routability prediction of a query chip. The method includes:
modeling a universal routability prediction task as a meta learning scenario, constructing a universal few-shot learner F, and by using chip data (support set S^{T}) with a same RTL design as an unseen chip design (query X^{q}), adapting to any routability prediction task T, to generate an accurate routability prediction Y_{q}=F (X_{q}, S^{T}), S^{T}={(Xᵢ, Yᵢ)}i≤N; and by using a meta training dataset Dₜᵣₐᵢₙ including a plurality of routability prediction tasks, training a routability prediction model through meta learning, to enable the routability prediction model to acquire general knowledge during a plurality of times of FSL processes;
to fully use spatial correlation information between a chip feature and a label, modeling the universal routability prediction task as a dense prediction problem T: X∈ [symbol] →Y∈ [symbol] and using four features widely used in the routability prediction task; and
for a routability prediction task t of a chip design, using, by the routability prediction model, a query

$${x}_{q}^{t}$$

and a support set

$${S}^{t} = {\{ ( {x}_{j}^{t} , {y}_{i}^{t} ) \}}_{i < N}$$

that is composed of a chip feature with the same RTL design and a label thereof as inputs; and in the support set, performing cascading by each chip feature and the label thereof in a channel dimension, and promoting information interaction between the support set and the query through a cross block, thereby accurately predicting a routability result

$${\hat{y}}_{q}^{t} = F ( {x}_{q}^{t} , {S}^{t} ) .$$

A specific implementation process of the present invention is as follows.

An embodiment provides a universal routability prediction method based on few-shot learning, which is specifically implemented as follows:
1. Modeling a universal routability prediction task as a meta learning scenario
in an iteration process of a chip design, the same RTL design is usually reused, and differentiated optimization is performed through an EDA process for different design targets, thereby accumulating abundant data annotations. A core of the present invention is to construct a universal few-shot learner F and flexibly adapt to any routability prediction task T by using chip data (a support set) S^{T} with the same RTL design as an unseen chip design (query) X_{q}, thereby generating an accurate routability prediction Y_{q}=F (X_{q}, S^{T}), S^{T}={(Xᵢ, Yᵢ)}i≤N. A meta training dataset Dₜᵣₐᵢₙ including a plurality of routability prediction tasks is used, and a model is trained through meta learning, to enable the model to acquire general knowledge during a plurality of FSL processes. The few-shot learner is flexibly adjusted based on the given support set S^{T}, to adapt to different tasks, thereby generating an accurate prediction for a query chip.
2. Feature extraction
Considering that a routability annotation is presented in a two-dimensional array format generally, to fully use spatial correlation information between a chip feature and a label, the universal routability prediction task is modeled as a dense prediction problem T: X∈ [symbol] →Y∈ [symbol] . Four features widely used in the routability prediction task are used: rectangular uniform wire density (RUDY), RUDY pin, macro region, and unit density.
3. Meta learning policy based on importance sampling
To cope with an inherent data imbalance problem, for example, interactions of a chip type, a design scale, a technical node, and other factors, an importance sampling technology is introduced for meta learning, to smoothly optimize losses of the model on different tasks. A target is to enable the model to self-adaptively perform task sampling [symbol] =Eₜ_{_{B}}₋ₚ_{^{t}}[L^{t}|p^{t}], where p^{t}μ \sqrt{E[L^{t2}]} and Σp^{t}=1 according to dynamic changes in different task losses L^{t} in a training process. Specifically, each task retains 10 recent historical loss values and performs dynamic updating in the training process. Before the training is started, a batch B of tasks t are selected through random sampling, and after 10 samples are collected for each task, the meta learning policy based on the importance sampling is initiated. In a task sampling phase, to introduce randomness and prevent the model from forgetting past knowledge, a constant γ=0.01 is added when a probability p^{t} of task sampling is calculated, and n is a quantity of tasks in the meta training dataset Dₜᵣₐᵢₙ. A batch B of tasks t_{B} are sampled based on p^{t}. A query

$${Q}_{b}^{t} ← ( {x}_{b}^{t} , {y}_{b}^{t} )$$

and a support set

$${S}_{b}^{t} ← {\{ ( {x}_{i}^{t} , {y}_{i}^{t} ) \}}_{i \leq N}$$

are sampled from each task t_{b∈B}. To prevent overfitting of the model on a specific task and improve data diversity, data enhancement is performed on the query

$${Q}_{b}^{t}$$

and the support set

$${S}_{b}^{t}$$

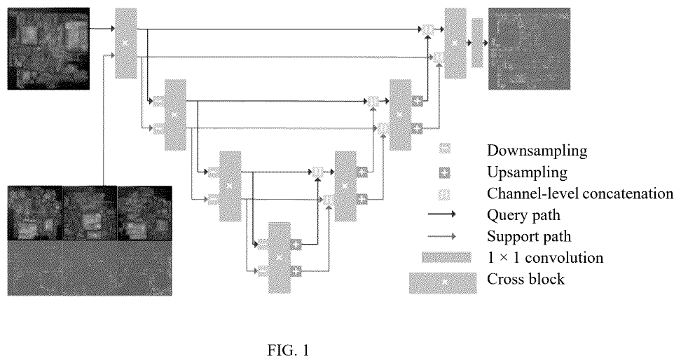

separately. Finally, the training improves accuracy of the routability prediction of the model for a given query under a condition that S^{t} is the support set, to enable the model to acquire general knowledge related to the FSL through the meta learning.
4. Model and inference
As shown in FIG. 1, to fully integrate cross-space scale information, UniverSeg is used as a backbone. For a routability prediction task t of a specific chip design, the model uses a query

$${x}_{q}^{t}$$

and a support set

$${S}^{t} = {\{ ( {x}_{i}^{t} , {y}_{i}^{t} ) \}}_{i \leq N}$$

composed of a chip feature with the same RTL design and a label thereof as inputs. In the support set, each chip feature and a label thereof perform cascading in a channel dimension, and information interaction between the support set and the query is promoted through a cross block, thereby accurately predicting a routability result

$${\hat{y}}_{q}^{t} = F ( {x}_{q}^{t} , {S}^{t} ) .$$

A quantity of annotations of chip data in the EDA field is variable and scarce, and the UniverSeg is used as the backbone, so that different sizes of support sets can be flexibly adapted, thereby better meeting application requirements of FSL in the EDA field.
5. FSL dataset
To train the model, a dataset used for the FSL is constructed based on CircuitNet and ISPD2015 datasets. The dataset includes different routability metric standards, technical nodes, chip types, scales, and the like. For different optimization targets, the same RTL design is usually reused. Therefore, under a specific technical node and metric, chip data annotations with the same RTL design are divided into one task. Datasets corresponding to these tasks include chip designs for performance, power consumption, areas, and other different optimization targets. All features and labels are resized to 256×256 pixels, and the labels are normalized to a range [0, 1] through max-min normalization. A dataset corresponding to each task constructs three disjoint splits d={dₛ,dᵥ,dₜ}, respectively containing 60%, 20%, and 20% of data. The model uses a support split dₛ and a test split dₜ in a training set to train the model and uses a verification split dᵥ to perform model selection and hyperparameter tuning.

The present invention further provides a universal routability prediction system based on few-shot learning, including a memory, a processor, and a computer program instruction that is stored on the memory and can be executed by the processor, where when the processor executes the computer program instruction, the method steps described above can be implemented.

The present invention further provides a computer-readable storage medium storing a computer program instruction that can be executed by a processor, where when the processor executes the computer program instruction, the method steps described above can be implemented.

A person skilled in the art should understand that embodiments of the present application may be provided as a method, a system, or a computer program product. Therefore, the present application may be in the form of a hardware only embodiment, a software only embodiment, or an embodiment with a combination of software and hardware. Moreover, the present application may be in the form of a computer program product that is implemented on one or more computer-usable storage media (including but not limited to a disk memory, a CD-ROM, an optical memory, and the like) that include computer-usable program code.

The present application is described with reference to the flowcharts and/or block diagrams of the method, the device (system), and the computer program product according to embodiments of this application. It should be understood that computer program instruction may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of another programmable data processing device to generate a machine, so that the instructions executed by the computer or the processor of the another programmable data processing device generate an apparatus for implementing a specific function in one or more processes in the flowcharts and/or in one or more blocks in the block diagrams.

These computer program instructions may be stored in a computer-readable memory that can instruct the computer or the another programmable data processing device to work in a specific manner, so that the instructions stored in the computer-readable memory generate an artifact that includes an instruction apparatus. The instruction apparatus implements a specific function in one or more processes in the flowcharts and/or in one or more blocks in the block diagrams.

These computer program instructions may alternatively be loaded onto the computer or the another programmable data processing device, so that a series of operations and steps are performed on the computer or the another programmable device, to generate computer-implemented processing. Therefore, the instructions executed on the computer or the another programmable device provide steps for implementing a specific function in one or more processes in the flowcharts and/or in one or more blocks in the block diagrams.

The above-described embodiments are only exemplary embodiments of the present invention and constitute no restriction in any form on the present invention. Those skilled in the art may make some changes or modifications to equivalent embodiments with equivalent changes by reference to the technical content disclosed above. However, any simple revisions, equivalent changes, and modifications made to the above embodiments in accordance with the technical essence of the present invention without departing from the content of the technical solutions of the present invention shall still fall within the protection scope of the technical solutions of the present invention.

What is claimed is:

1. A universal routability prediction method based on few-shot learning, wherein a universal routability prediction is converted into a meta learning scenario, and a prediction method based on the few-shot learning (FSL) is provided, to implement a routability prediction of a query chip.

2. The universal routability prediction method based on few-shot learning according to claim 1, wherein the method comprises:
defining a universal routability prediction task T of a chip layout divided into a W×H grid as T: X→∈ [symbol] , wherein X represents a used chip feature;
and the task comprises different routability metrics, technical nodes, chip types, and RTL designs;
modeling the universal routability prediction task as a meta learning scenario, constructing a universal few-shot learner F, and by using chip data (support set S^{T}) with a same RTL design as an unseen chip design (query X_{q}), adapting to any routability prediction task T, to generate an accurate routability prediction Y_{q}=F (X_{q},S^{T}), S^{T}={(Xᵢ, Yᵢ)}i≤N; and by using a meta training dataset Dₜᵣₐᵢₙ comprising a plurality of routability prediction tasks, training a routability prediction model through meta learning, to enable the routability prediction model to acquire general knowledge during a plurality of times of FSL processes;
to fully use spatial correlation information between a chip feature and a label, modeling the universal routability prediction task as a dense prediction problem T: X∈ [symbol] →Y∈ [symbol] , and using four features widely used in the routability prediction task; and
for a routability prediction task t of a chip design, using, by the routability prediction model, a query
$${x}_{q}^{t}$$
and a support set
$${S}^{t} = {\{ ( {x}_{i}^{t} , {y}_{i}^{t} ) \}}_{i \leq N}$$
that is composed of a chip feature with the same RTL design and a label thereof as inputs; and in the support set, performing cascading by each chip feature and the label thereof in a channel dimension, and promoting information interaction between the support set and the query through a cross block, thereby accurately predicting a routability result
$${\hat{y}}_{q}^{t} = F ( {x}_{q}^{t} , {S}^{t} ) .$$

3. The universal routability prediction method based on few-shot learning according to claim 2, wherein in the training the routability prediction model through meta learning, to enable the routability prediction model to acquire general knowledge during a plurality of times of FSL processes, an importance sampling technology is introduced for the meta learning, to optimize losses of the model on different tasks, and a target is to enable the model to self-adaptively perform task sampling [symbol] = [symbol] [L^{t}/p^{t}], where p^{t}μ \sqrt{E[L^{t2}]} and Σp^{t}=1 according to dynamic changes of different task losses L^{t} in a training process; and each task retains 10 recent historical loss values and performs dynamic updating in the training process.

4. The universal routability prediction method based on few-shot learning according to claim 3, wherein before the training is started, a batch B of tasks t are selected through random sampling, and after 10 samples are collected for each task, a meta learning policy based on importance sampling is initiated: in a task sampling phase, to introduce randomness and prevent the model from forgetting past knowledge, a constant γ=0.01 is added when a probability p^{t} of task sampling is calculated, and a quantity of tasks in the meta training dataset Dₜᵣₐᵢₙ is n; a batch B of tasks t_{B} are sampled based on p^{t}; a query
$${Q}_{b}^{t} ← ( {x}_{b}^{t} , {y}_{b}^{t} )$$
and a support set
$${S}_{b}^{t} ← {\{ ( {x}_{i}^{t} , {y}_{i}^{t} ) \}}_{i \leq N}$$
are sampled from each task t_{b∈B}; to prevent overfitting of the model on a specific task and improve data diversity, data enhancement is performed on the query
$${Q}_{b}^{t}$$
and the support set
$${S}_{b}^{t}$$
separately; and finally, the training improves accuracy of the routability prediction of the model for a given query under a condition that S^{t} is the support set, to enable the model to acquire general knowledge related to the FSL through the meta learning.

5. The universal routability prediction method based on few-shot learning according to claim 2, wherein the four features widely used in the routability prediction task are: Rectangular Uniform Wire Density (RUDY), RUDY pin, macro region, and unit density.

6. The universal routability prediction method based on few-shot learning according to claim 2, wherein in a process of accurately predicting the routability result
$${\hat{y}}_{q}^{t} = F ( {x}_{q}^{t} , {S}^{t} )$$
for the routability prediction task t of the chip design, UniverSeg is used as a backbone, to adapt to different sizes of support sets.

7. The universal routability prediction method based on few-shot learning according to claim 2, wherein the meta training dataset Dₜᵣₐᵢₙ is constructed based on CircuitNet and ISPD2015 datasets.

8. The universal routability prediction method based on few-shot learning according to claim 7, wherein a dataset corresponding to each routability prediction task of the chip design constructs three disjoint splits d={dₛ,dᵥ,dₜ}, respectively containing 60%, 20%, and 20% of data; and the model uses a support split dₛ and a test split dₜ in a training set to train the model and uses a verification split dᵥ to perform model selection and hyperparameter tuning.

9. A universal routability prediction system based on few-shot learning, comprising a memory, a processor, and a computer program instruction that is stored on the memory and can be executed by the processor, wherein when the processor executes the computer program instruction, the method steps according to claim 1 can be implemented.

10. A computer-readable storage medium storing a computer program instruction that can be executed by a processor, wherein when the processor executes the computer program instruction, the method steps according to claim 1 can be implemented.
